(19) United States
(12) Patent Application Publication
(10) Pub. No.: US 2026/0208284 A1
(43) Pub. Date: Jul. 23, 2026

(54) METHOD FOR MANUFACTURING SHOWER HEAD FOR SEMICONDUCTOR MANUFACTURING USING AN IMPROVED DIFFUSION BONDING PROCESS

(71) Applicant: TNP CORPORATION, Chungcheongbuk-do (KR)

(72) Inventors: Kye Nam LEE, Chungcheongbuk-do (KR); Tae Kyoung KIM, Chungcheongbuk-do (KR)

(21) Appl. No.: 19/400,367

(22) Filed: Nov. 25, 2025

(30) Foreign Application Priority Data
Jan. 23, 2025 (KR) 10-2025-0010066

(51) Int. Cl. B23K 20/02; B23K 101/10; B23K 103/10; C23C 16/455

(52) U.S. Cl. CPC B23K 20/023; B23K 2101/10; B23K 2103/10; C23C 16/45565

(57) ABSTRACT

A method for manufacturing a shower head for semiconductor manufacturing using an improved diffusion bonding process is disclosed. The method includes a first diffusion bonding step of bonding an end plate and a middle plate using diffusion bonding to manufacture a lower structure; and a second diffusion bonding step of bonding a top plate to the lower structure using diffusion bonding to manufacture the shower head.

### CROSS-REFERENCE TO RELATED APPLICATIONS

This application claims the priority of Korean Patent Application No. 10-2025-0010066 filed on Jan. 23, 2025, in the Korean Intellectual Property Office, the disclosure of which is incorporated herein by reference.

### FIELD

The present disclosure relates to a method for manufacturing a shower head for semiconductor manufacturing using an improved diffusion bonding process.

### BACKGROUND

As the high integration of semiconductor devices proceeds, the necessity to more precisely control process conditions and environments in the manufacture of semiconductor devices is increasing. For example, as the large-diameter scaling of substrates (wafers) continues, efforts are being made to secure process uniformity within the substrate as well as between substrates, in other words, to achieve uniform process results across the entire surface of the substrate.

In particular, structural changes to improve process uniformity are being studied in equipment having a shower head as a device for supplying process gas for chemical vapor deposition (CVD) or etching on the substrate surface for semiconductor device manufacturing. For instance, shower heads are changing to a multi-layer structure to improve deposition uniformity, reduce particle contamination, improve process condition control, and enhance process efficiency in the semiconductor substrate processing process.

FIG. 1 is a view schematically showing an example of a conventional multi-layer shower head. The conventional shower head 1 has a structure in which an end plate 30, a middle plate 20, and a top plate 10 are stacked from bottom to top. The top plate 10 is supplied with process gas, and the middle plate 20 uniformly diffuses the process gas supplied from the top plate 10. The end plate 30 further evenly distributes the process gas supplied from the middle plate 20 to maintain uniform gas pressure and injects the gas so that it is evenly distributed toward the substrate side. To this end, a process gas inlet 12 to which a process gas supply port (not shown) is connected is formed in the top plate 10, connecting holes 22 are formed in the middle plate 20, and fine injection holes 32 are formed in the end plate 30.

Meanwhile, the conventional shower head 1 is manufactured by stacking the middle plate 20 on the end plate 30 and welding the inner and outer parts contacting each other, and then stacking the top plate 10 on the middle plate 20 and welding the inner and outer parts contacting each other. However, since the conventional shower head 1 is laminated through high-temperature welding, there is a limit to stacking the middle plate 20 in multiple layers, for example, three or more layers, between the end plate 30 and the top plate 10. In addition, due to the thermal characteristics of high-temperature welding (550~1300° C.), there is a limitation that the top plate 10, middle plate 20, and end plate 30 must be made of special metals (SUS, Ta, TaN, Ti, TiN) with excellent strength at high temperatures.

Furthermore, due to the slag remaining area P generated during welding, there are problems such as deformation in the size and shape of the connecting holes 22 and injection holes 32 and hole non-uniformity. Additionally, since the shape of the welded part is not constant, the quality of the shower head 1, such as strength, airtightness, and lifespan, is degraded, which causes other problems leading to quality degradation and yield reduction of semiconductor devices.

### SUMMARY

An aspect of the present disclosure is to provide a method for manufacturing a shower head for semiconductor manufacturing using an improved diffusion bonding process that can prevent the injection holes of the end plate and the connecting holes of the middle plate from being deformed or damaged.

Another aspect of the present disclosure is to provide a method for manufacturing a shower head for semiconductor manufacturing using an improved diffusion bonding process that allows each layer to be uniformly bonded even if three or more layers of middle plates are stacked between the end plate and the top plate.

Still another aspect of the present disclosure is to provide a method for manufacturing a shower head for semiconductor manufacturing using an improved diffusion bonding process that allows expanding the range of materials for the end plate, middle plate, and top plate.

To achieve the above objects, embodiments according to the present disclosure provide a method for manufacturing a shower head for semiconductor manufacturing, comprising: a first diffusion bonding step (S1) of bonding an end plate and a middle plate using diffusion bonding to manufacture a lower structure; and a second diffusion bonding step (S2) of bonding a top plate to the lower structure using diffusion bonding to manufacture the shower head. The end plate, the middle plate, and the top plate are formed of aluminum or an aluminum alloy.

The first diffusion bonding step (S1) includes: a first preparation step (S1-1) of stacking the middle plate on the end plate and fixing them in a work chamber for diffusion bonding; a first preheating step (S1-2) of creating an environment where atoms can move by applying heat and pressure to the end plate and the middle plate; a first stabilization step (S1-3) of promoting bonding quality improvement by applying heat and pressure to the bonding surfaces of the end plate and the middle plate; and a first bonding step (S1-4) of bonding by applying heat and pressure to the bonding surfaces of the end plate and the middle plate.

The first bonding step (S1-4) is characterized by manufacturing the lower structure by raising the temperature inside the work chamber to 0.86 to 0.94 times the melting point of the end plate and the middle plates while applying a pressure of 2.7 to 7.4 MPa to the bonding surfaces of the end plate and the middle plate, maintaining the pressure and temperature for 140 to 160 minutes, then cooling the internal temperature of the work chamber to room temperature for 200 to 280 minutes, and simultaneously releasing the pressure rapidly for 10 to 20 minutes.

In embodiments according to the present disclosure, the first preparation step (S1-1) is characterized by maintaining the inside of the work chamber in a high vacuum state of 10E-4 torr after replacing the air inside the work chamber with inert gas 2 to 3 times.

In embodiments according to the present disclosure, the first preheating step (S1-2) is characterized by raising the temperature inside the work chamber to 0.68 to 0.78 times the melting point of the end plate and the middle plate while applying a pressure of 0.9 to 2.5 MPa to the bonding surfaces of the end plate and the middle plate, and then maintaining the pressure and temperature for 20 minutes.

In embodiments according to the present disclosure, the first stabilization step (S1-3) is characterized by raising the temperature inside the work chamber to 0.8 to 0.85 times the melting point of the end plate and the middle plate while applying a pressure of 0.9 to 2.5 MPa to the bonding surfaces of the end plate and the middle plate, and then maintaining the pressure and temperature for 100 to 140 minutes.

In embodiments according to the present disclosure, the first preparation step (S1-1) is characterized by stacking three or more middle plates.

In embodiments according to the present disclosure, the second diffusion bonding step (S2) includes: a second preparation step (S2-1) of stacking the top plate on the lower structure and fixing them in a work chamber for diffusion bonding; a second preheating step (S2-2) of creating an environment where atoms can move by applying heat and pressure to the lower structure and the top plate; a second stabilization step (S2-3) of promoting bonding quality improvement by applying heat and pressure to the bonding surfaces of the lower structure and the top plate; and a second bonding step (S2-4) of bonding by applying heat and pressure to the bonding surfaces of the lower structure and the top plate.

In embodiments according to the present disclosure, the second bonding step (S2-4) is characterized by manufacturing the shower head by raising the temperature inside the work chamber to 0.86 to 0.94 times the melting point of the lower structure and the top plate while applying a pressure of 0.7 to 2.45 MPa to the bonding surfaces of the lower structure and the top plate, maintaining the pressure and temperature for 360 to 460 minutes, and then cooling the internal temperature of the work chamber to room temperature for 200 to 280 minutes.

In embodiments according to the present disclosure, the second preparation step (S2-1) is characterized by maintaining the inside of the work chamber in a high vacuum state of 10E-4 torr after replacing the air inside the work chamber with inert gas 2 to 3 times.

In embodiments according to the present disclosure, the second preheating step (S2-2) is characterized by raising the temperature inside the work chamber to 0.68 to 0.78 times the melting point of the lower structure and the top plates while applying a pressure of 0.4 to 0.5 MPa to the bonding surfaces of the lower structure and the top plate, and then maintaining the pressure and temperature for 20 minutes.

In embodiments according to the present disclosure, the second stabilization step (S2-3) is characterized by raising the temperature inside the work chamber to 0.8 to 0.85 times the melting point of the lower structure and the top plate while applying a pressure of 0.4 to 0.5 MPa to the bonding surfaces of the lower structure and the top plate, and then maintaining the pressure and temperature for 100 to 140 minutes.

According to the present disclosure, since the end plate, middle plates, and top plate are combined using a diffusion bonding process, the bonding strength between plates can be increased while preventing deformation and damage to the injection holes and connecting holes. This minimizes process interruptions and increases productivity through extending the lifespan and maintaining the performance of the shower head.

Also, since three or more layers of middle plates can be stacked between the end plate and the top plate, the shower head can be precisely designed, increasing versatility applicable to various processes. Different materials or structures can be applied for each plate to optimize specific performances of the shower head. Ultimately, it enables fine processing of the injection holes of the end plate, promoting the stability of the semiconductor manufacturing process through uniform process gas injection, thereby enabling quality improvement and yield improvement.

Furthermore, the degree of freedom in design can be increased by expanding the choice of materials for the end plate, middle plate, and top plate, and production costs can be reduced by using inexpensive materials. Therefore, the present disclosure contributes to strengthening the competitiveness of the semiconductor industry and producing more precise and efficient semiconductor products.

### BRIEF DESCRIPTION OF THE DRAWINGS

FIG. 1 is a view schematically showing an example of a conventional multi-layer shower head.

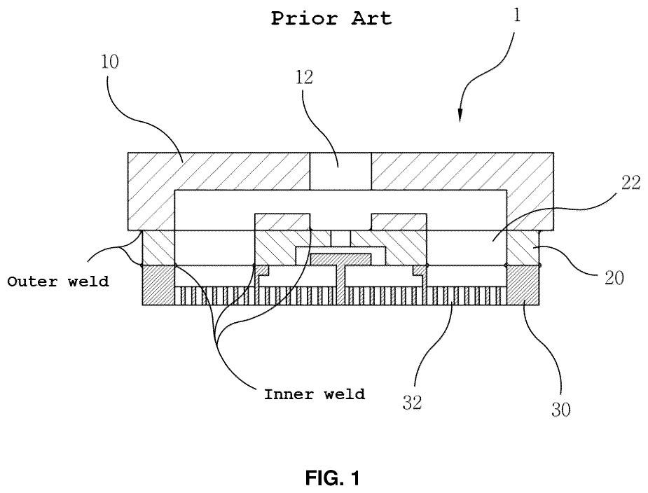

FIG. 2 is a view schematically showing an example of a shower head manufactured according to the present disclosure.

FIG. 3 is a flowchart showing a method for manufacturing a shower head for semiconductor manufacturing using an improved diffusion bonding process according to the present disclosure.

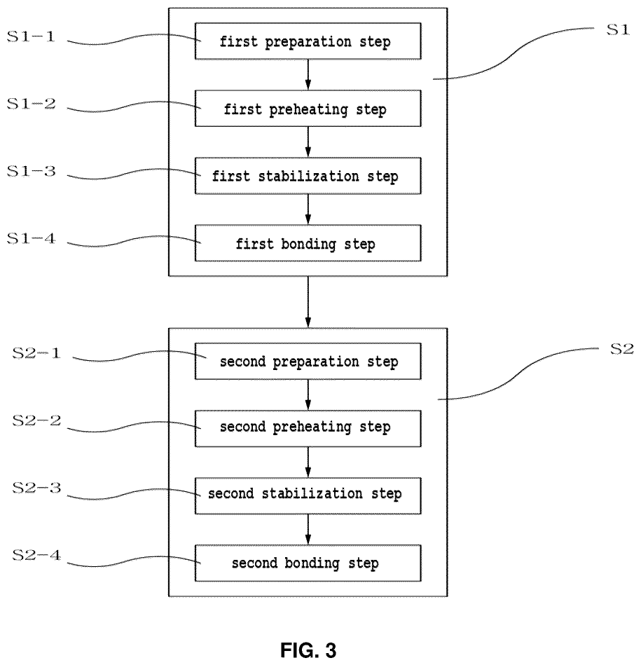

### DETAILED DESCRIPTION

Hereinafter, embodiments implementing the method for manufacturing a shower head for semiconductor manufacturing using an improved diffusion bonding process according to the present disclosure will be described in detail with reference to the drawings.

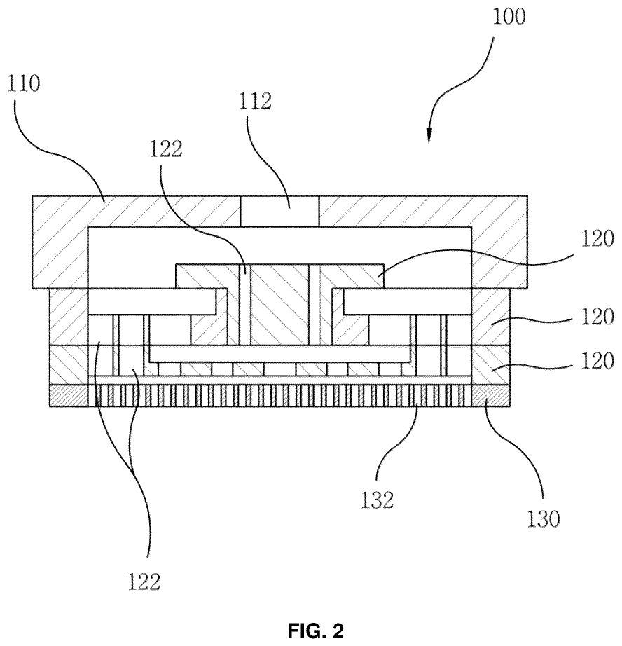

FIG. 2 is a view schematically showing an example of a shower head according to the present disclosure.

Like the conventional shower head (10), the shower head (100) according to the present disclosure has a structure in which an end plate (130) having injection holes (132), a middle plate (120) having connecting holes (122), and a top plate (110) having a process gas inlet (112) are stacked from bottom to top.

However, unlike the conventional shower head (10), the shower head (100) according to the present disclosure has a structure in which three or more middle plates (120) are stacked between the end plate (130) and the top plate (110).

Here, the shapes of the top plate (110), middle plates (120), and end plate (130) are not particularly limited in the present disclosure.

In other words, the top plate (110), middle plates (120), and end plate (130) may be designed and changed to be applicable to various processes.

In addition, the top plate (110), middle plates (120), and end plate (130) constituting the shower head (100) according to the present disclosure may be formed of homogeneous metals or heterogeneous metals having a melting point of approximately 660° C. or less.

Preferably, the top plate (110), middle plates (120), and end plate (130) may be formed of aluminum or aluminum alloy (6061 series).

Further, the injection holes (132) formed in the end plate (130) may be formed to have a fine diameter exceeding 0 and up to 2 mm.

The top plate (110), middle plates (120), and end plate (130) of the shower head (100) formed as described above are uniformly bonded through an improved diffusion bonding process.

The method for manufacturing a shower head for semiconductor manufacturing using the improved diffusion bonding process according to the present disclosure will be described below.

The present disclosure divides the diffusion bonding process into a first diffusion bonding step (S1) and a second diffusion bonding step (S2).

Optimized heating and pressurizing conditions are applied in the first diffusion bonding step (S1) and the second diffusion bonding step (S2) so that the top plate (110), middle plates (120), and end plate (130) are uniformly bonded (joined) without deformation and damage to the injection holes (132) and connecting holes (122).

### 1. First Diffusion Bonding Step (S1)

The first diffusion bonding step (S1) bonds the end plate (130) and the middle plates (120) using diffusion bonding to manufacture a lower structure.

The first diffusion bonding step (S1) includes a first preparation step (S1-1), a first preheating step (S1-2), a first stabilization step (S1-3), and a first bonding step (S1-4).

In the first preparation step (S1-1), the middle plates (120) are stacked on the end plate (130), which is the object to be bonded, according to a preset design and fixed in a work chamber for diffusion bonding.

And in the first preparation step (S1-1), after replacing (purging) the air inside the work chamber with inert gas (nitrogen) 2 to 3 times to remove oxygen and moisture, the inside of the work chamber is maintained in a high vacuum state of 10E-4 torr.

Here, if the air replacement inside the work chamber using inert gas is less than 2 times, oxygen and moisture may remain in the work chamber, causing oxidation or corrosion of the bonding target. If the air replacement exceeds 3 times, no further air replacement effect can be expected, and the process time becomes longer.

Also, if the vacuum degree inside the work chamber is less than 10E-4 torr, gas remains inside the work chamber, and gas molecules may cause contamination on the bonding surface, reducing bonding strength. If the vacuum degree exceeds 10E-4 torr, the evaporation rate increases, which may thin the bonding surface.

The first preheating step (S1-2) creates an environment where atoms can move by applying heat and pressure to the end plate (130) and middle plates (120).

In the first preheating step (S1-2), the end plate (130) and middle plates (120) are pressurized so that a pressure of 0.9~2.5 MPa (2~5 tons/20000 m²) is applied to the bonding surfaces.

At the same time, the temperature inside the work chamber is raised to 0.68~0.78 times the melting point of the end plate (130) and middle plates (120), and then the pressure and temperature are maintained for 20 minutes.

Here, if the pressure is less than 0.9 MPa, fine gaps may occur between the bonding surfaces, preventing smooth atomic diffusion. If the pressure exceeds 2.5 MPa, deformation may occur in the end plate (130) or middle plate (120), causing uneven bonding surfaces and potentially deforming or damaging the injection holes (132) and connecting holes (122).

If the internal temperature of the work chamber is less than 0.68 times, the kinetic energy of atoms decreases, slowing down the diffusion rate. If the internal temperature exceeds 0.78 times, the bonding surface may melt and become unstable, or pores may occur.

Also, if the holding time is less than 20 minutes, heat is not applied to the bonding surface for a sufficient time, leading to incomplete bonding due to insufficient atomic diffusion. If the holding time exceeds 20 minutes, grain growth occurs, changing the properties of the bonding surface, which can deform and damage the injection holes (132) and connecting holes (122).

The first stabilization step (S1-3) applies heat and pressure to the end plate (130) and middle plates (120) to improve bonding quality.

In the first stabilization step (S1-3), the end plate (130) and middle plates (120) are pressurized so that a pressure of 0.9~2.5 MPa (2~5 tons/20000 m²) is applied to the bonding surfaces.

At the same time, the temperature inside the work chamber is raised to 0.8~0.85 times the melting point of the end plate (130) and middle plates (120), and then the pressure and temperature are maintained for 100~140 minutes.

Here, if the pressure is less than 0.9 MPa, the bonding surfaces may not be in complete contact, weakening bonding strength. If the pressure exceeds 2.5 MPa, the bonding surfaces may deform or break, causing deformation and damage to the injection holes (132) and connecting holes (122).

If the internal temperature is less than 0.8 times, atoms may not move sufficiently, leading to incomplete bonding. If it exceeds 0.85 times, the bonding surface may soften or deform, damaging the injection holes (132) and connecting holes (122).

Also, if the holding time is less than 100 minutes, atoms may not diffuse sufficiently, weakening bonding strength. If it exceeds 140 minutes, atoms may diffuse excessively, making the mixed layer of the bonding surface too thick, which rather lowers bonding strength and causes deformation and damage to the injection holes (132) and connecting holes (122).

The first bonding step (S1-4) is performed to strongly bond the bonding surfaces of the end plate (130) and middle plates (120) by applying heat and pressure.

In the first bonding step (S1-4), the end plate (130) and middle plates (120) are pressurized so that a pressure of 2.7~7.4 MPa (6~15 tons/20000 m²) is applied to the bonding surfaces.

At the same time, while the temperature inside the work chamber is raised to 0.86~0.94 times the melting point of the end plate (130) and middle plates (120), the pressure and temperature are maintained for 140~160 minutes.

Then, the internal temperature of the work chamber is cooled to room temperature for 200~280 minutes to manufacture the lower structure in which the end plate (130) and middle plates (120) are bonded.

Here, if the pressure is less than 2.7 MPa, the bonding surfaces may not be in complete contact, leaving voids and weakening bonding strength. If the pressure exceeds 7.4 MPa, excessive pressure may deform or destroy the bonding surfaces, thereby deforming and damaging the injection holes (132) and connecting holes (122).

If the internal temperature is less than 0.86 times, atoms may not move sufficiently, resulting in incomplete bonding. If it exceeds 0.94 times, the bonding surface may soften or deform, leading to deformation and damage to the injection holes (132) and connecting holes (122).

In addition, if the holding time is less than 140 minutes, atoms may not diffuse sufficiently, weakening bonding strength, and time for completely relieving residual stress is not secured. If the holding time exceeds 160 minutes, atoms diffuse excessively, making the mixed layer of the bonding surface too thick, potentially deforming and damaging the injection holes (132) and connecting holes (122).

If the cooling time is less than 200 minutes, thermal stress may be generated, causing cracks or deformation on the bonding surface. If the cooling time exceeds 280 minutes, productivity may decrease.

Meanwhile, the pressure in the first bonding step (S1-4) is rapidly released for 10 to 20 minutes while cooling the internal temperature of the work chamber.

Here, if the pressure is released in less than 10 minutes, thermal stress may concentrate on the bonding surface, causing cracks. If released over more than 20 minutes, residual stress may remain on the bonding surface.

### 2. Second Diffusion Bonding Step (S2)

The second diffusion bonding step (S2) bonds the top plate (110) to the lower structure manufactured in the first diffusion bonding step (S1) using diffusion bonding to manufacture the shower head (100) according to the present disclosure.

The second diffusion bonding step (S2) includes a second preparation step (S2-1), a second preheating step (S2-2), a second stabilization step (S2-3), and a second bonding step (S2-4).

In the second preparation step (S2-1), the top plate (110) is stacked on the lower structure, which is the object to be bonded, according to a preset design and fixed in a work chamber for diffusion bonding.

And in the second preparation step (S2-1), after replacing (purging) the air inside the work chamber with inert gas (nitrogen) 2 to 3 times to remove oxygen and moisture, the inside of the work chamber is maintained in a high vacuum state of 10E-4 torr.

Here, replacing the air inside the work chamber with inert gas (nitrogen) 2 to 3 times and maintaining the vacuum degree at 10E-4 torr are performed for the same purpose as the first preparation step (S1-1) of the first diffusion bonding step (S1), so detailed description thereof is omitted.

The second preheating step (S2-2) creates an environment where atoms can move by applying heat and pressure to the lower structure and the top plate (110). In the second preheating step (S2-2), the lower structure and the top plate (110) are pressurized so that a pressure of 0.4~0.5 MPa (1 ton or less/20000 m²) is applied to the bonding surfaces.

At the same time, the temperature inside the work chamber is raised to 0.68~0.78 times the melting point of the lower structure and top plate (110), and then the pressure and temperature are maintained for 20 minutes.

Here, if the pressure is less than 0.4 MPa, fine gaps may occur between bonding surfaces, preventing smooth atomic diffusion. If the pressure exceeds 0.5 MPa, it may cause deformation in the bonding surfaces of the lower structure and between the lower structure and top plate (110), resulting in uneven bonding surfaces and potentially deforming and damaging the injection holes (132) and connecting holes (122).

If the internal temperature is less than 0.68 times, the kinetic energy of atoms decreases, slowing diffusion. If it exceeds 0.78 times, the bonding surface may melt and become unstable or pores may occur.

Also, if the holding time is less than 20 minutes, sufficient heat is not applied, leading to incomplete bonding. If it exceeds 20 minutes, grain growth occurs, changing bonding surface properties and potentially causing deformation/damage to holes (132, 122).

The second stabilization step (S2-3) applies heat and pressure to the bonding surfaces of the lower structure and top plate (110) to improve bonding quality. In the second stabilization step (S2-3), the lower structure and top plate (110) are pressurized so that a pressure of 0.4~0.5 MPa (2 ~5 tons/20000 m²) is applied to the bonding surfaces.

At the same time, the temperature inside the work chamber is raised to 0.8~0.85 times the melting point of the lower structure and top plate (110), and then the pressure and temperature are maintained for 100~140 minutes.

Here, if pressure is less than 0.4 MPa, bonding surfaces may not fully contact, weakening strength. If it exceeds 0.5 MPa, bonding surfaces may deform or break, causing damage to holes (132, 122).

If temperature is less than 0.8 times, incomplete bonding may occur. If it exceeds 0.85 times, bonding surfaces may soften/deform, damaging holes (132, 122).

If holding time is less than 100 minutes, diffusion is insufficient. If it exceeds 140 minutes, excessive diffusion thickens the mixed layer, reducing strength and damaging holes.

The second bonding step (S2-4) is performed to strongly bond the bonding surfaces of the lower structure and top plate (110) by applying heat and pressure. In the second bonding step (S2-4), the lower structure and top plate (110) are pressurized so that a pressure of 0.7~2.45 MPa (1~5 tons/20000 m²) is applied to the bonding surfaces.

At the same time, while the temperature inside the work chamber is raised to 0.86~0.94 times the melting point of the lower structure and top plate (110), the pressure and temperature are maintained for 360~460 minutes. Then, the internal temperature is cooled to room temperature for 200~280 minutes to manufacture the shower head (100).

Here, if pressure is less than 0.7 MPa, bonding surfaces may not fully contact, leaving voids. If it exceeds 2.45 MPa, excessive pressure may deform/destroy bonding surfaces, damaging holes (132, 122).

If temperature is less than 0.86 times, bonding is incomplete. If it exceeds 0.94 times, surfaces may soften/deform, damaging holes.

If holding time is less than 360 minutes, diffusion is insufficient and residual stress remains. If it exceeds 460 minutes, excessive diffusion thickens the mixed layer, damaging holes.

If cooling time is less than 200 minutes, thermal stress causes cracks/deformation. If it exceeds 280 minutes, productivity decreases.

According to the present disclosure, since the end plate (130), middle plates (120), and top plate (110) are diffusion bonded in first and second stages, bonding strength between plates can be increased while preventing deformation and damage to injection holes (132) and connecting holes (122).

This minimizes process interruptions through extending lifespan and maintaining performance of the shower head (100), and improves quality and productivity (Yield) of semiconductor devices through uniform process gas injection.

Also, since three or more layers of middle plates (120) can be stacked, the shower head (100) can be precisely designed, increasing versatility, and specific performance such as process uniformity can be optimized by applying different materials or structures per plate.

Furthermore, design freedom is increased by expanding material choices, and production costs can be reduced by using inexpensive materials.

What is claimed is:

1. A method for manufacturing a shower head for semiconductor manufacturing, the method comprising:
performing a first diffusion bonding step (S1) of bonding an end plate and a middle plate using diffusion bonding to manufacture a lower structure; and
performing a second diffusion bonding step (S2) of bonding a top plate to the lower structure using diffusion bonding to manufacture the shower head,
wherein the end plate, the middle plate, and the top plate are formed of aluminum or an aluminum alloy,
wherein the first diffusion bonding step (S1) comprises:
a first preparation step (S1-1) of stacking the middle plate on the end plate and fixing the stacked plates in a work chamber for diffusion bonding;
a first preheating step (S1-2) of applying heat and pressure to the end plate and the middle plate to create an environment for atomic movement;
a first stabilization step (S1-3) of applying heat and pressure to a bonding surface of the end plate and the middle plate to improve bonding quality; and
a first bonding step (S1-4) of bonding the end plate and the middle plate by applying heat and pressure to the bonding surface, and
wherein the first bonding step (S1-4) includes manufacturing the lower structure by:
raising a temperature inside the work chamber to 0.86 to 0.94 times a melting point of the end plate and the middle plate while applying a pressure of 2.7 to 7.4 MPa to the bonding surface;
maintaining the pressure and the temperature for 140 to 160 minutes; and
subsequently cooling the temperature inside the work chamber to room temperature for 200 to 280 minutes while rapidly releasing the pressure for 10 to 20 minutes.

2. The method of claim 1, wherein the first preparation step (S1-1) comprises:
replacing air inside the work chamber with an inert gas 2 to 3 times; and
subsequently maintaining the inside of the work chamber in a high vacuum state of 10E-4 Torr.

3. The method of claim 2, wherein the first preheating step (S1-2) comprises:
raising the temperature inside the work chamber to 0.68 to 0.78 times the melting point of the end plate and the middle plate while applying a pressure of 0.9 to 2.5 MPa to the bonding surface; and
subsequently maintaining the pressure and the temperature for 20 minutes.

4. The method of claim 3, wherein the first stabilization step (S1-3) comprises:
raising the temperature inside the work chamber to 0.8 to 0.85 times the melting point of the end plate and the middle plate while applying a pressure of 0.9 to 2.5 MPa to the bonding surface; and
subsequently maintaining the pressure and the temperature for 100 to 140 minutes.

5. The method of claim 1, wherein the first preparation step (S1-1) comprises stacking three or more middle plates.

6. The method of claim 4, wherein the second diffusion bonding step (S2) comprises:
a second preparation step (S2-1) of stacking the top plate on the lower structure and fixing the stacked structure in the work chamber for diffusion bonding;
a second preheating step (S2-2) of applying heat and pressure to the lower structure and the top plate to create an environment for atomic movement;
a second stabilization step (S2-3) of applying heat and pressure to a bonding surface of the lower structure and the top plate to improve bonding quality; and
a second bonding step (S2-4) of bonding the lower structure and the top plate by applying heat and pressure to the bonding surface of the lower structure and the top plate.

7. The method of claim 6, wherein the second bonding step (S2-4) comprises manufacturing the shower head by:
raising the temperature inside the work chamber to 0.86 to 0.94 times a melting point of the lower structure and the top plate while applying a pressure of 0.7 to 2.45 MPa to the bonding surface of the lower structure and the top plate;
maintaining the pressure and the temperature for 360 to 460 minutes; and
subsequently cooling the temperature inside the work chamber to room temperature for 200 to 280 minutes.

8. The method of claim 7, wherein the second preparation step (S2-1) comprises:
replacing air inside the work chamber with an inert gas 2 to 3 times; and
subsequently maintaining the inside of the work chamber in a high vacuum state of 10E-4 Torr.

9. The method of claim 8, wherein the second preheating step (S2-2) comprises:
raising the temperature inside the work chamber to 0.68 to 0.78 times the melting point of the lower structure and the top plate while applying a pressure of 0.4 to 0.5 MPa to the bonding surface of the lower structure and the top plate; and
subsequently maintaining the pressure and the temperature for 20 minutes.

10. The method of claim 9, wherein the second stabilization step (S2-3) comprises:
raising the temperature inside the work chamber to 0.8 to 0.85 times the melting point of the lower structure and the top plate while applying a pressure of 0.4 to 0.5 MPa to the bonding surface of the lower structure and the top plate; and
subsequently maintaining the pressure and the temperature for 100 to 140 minutes.
